(19) United States
(12) Patent Application Publication
(10) Pub. No.: US 2011/0308589 A1
(43) Pub. Date: Dec. 22, 2011

(54) PHOTOELECTRIC CONVERSION DEVICE AND METHOD FOR MANUFACTURING THE SAME

(75) Inventors: Riho Kataishi, Atsugi (JP); Kazutaka Kuriki, Ebina (JP)

(73) Assignee: SEMICONDUCTOR ENERGY LABORATORY CO., LTD., Atsugi-shi, Kanagawa-ken (JP)

(21) Appl. No.: 13/159,900

(22) Filed: Jun. 14, 2011

(30) Foreign Application Priority Data
Jun. 18, 2010 (JP) 2010-139997

(51) Int. Cl. H01L 31/06; H01L 31/18

(52) U.S. Cl. 136/255; 438/98; 257/E31.124

(57) ABSTRACT

An object of the present invention is to provide a photoelectric conversion device having a novel anti-reflection structure. An uneven structure is formed on a surface of a semiconductor by growth of the same or a different kind of semiconductor instead of forming an anti-reflection structure by etching a surface of a semiconductor substrate or a semiconductor film. For example, a semiconductor layer including a plurality of projections is provided on a light incident plane side of a photoelectric conversion device, thereby considerably reducing surface reflection. Such a structure can be formed by a vapor deposition method; therefore, the contamination of the semiconductor is not caused.

### BACKGROUND OF THE INVENTION

1. Field of the Invention

The present invention relates to a photoelectric conversion device and a method for manufacturing the same.

2. Description of the Related Art

Recently, a photoelectric conversion device, which is a power generation means that generates power without carbon dioxide emissions, has attracted attention as a countermeasure against global warming. A solar cell for supplying residential power or the like, which generates power from sunlight outdoors, is known as a typical example thereof. For such a solar cell, a crystalline silicon solar cell using single crystal silicon or polycrystalline silicon is mainly used.

An uneven structure is provided on a surface of a solar cell using a single crystal silicon substrate or a polycrystalline silicon substrate in order to reduce surface reflection. The uneven structure provided on the surface of the silicon substrate is formed by etching the silicon substrate with an alkaline solution such as NaOH. The etching rate by the alkaline solution varies depending on a crystal plane orientation of silicon. Therefore, when a silicon substrate with a (100) plane is used for example, a pyramidal uneven structure is formed.

Although the above-described uneven structure can reduce surface reflection of the solar cell, the alkaline solution used for etching causes contamination of the silicon semiconductor. In addition, since etching characteristics considerably vary depending on the concentration or temperature of the alkaline solution, it is difficult to form the uneven structure on the surface of the silicon substrate with high reproducibility. For the difficulty, a combination method of a laser processing technique and chemical etching is disclosed (for example, see Patent Document 1).

On the other hand, in a solar cell whose photoelectric conversion layer is formed using a semiconductor thin film of silicon or the like, it is difficult to form an uneven structure on a surface of the silicon thin film by etching using the above-described alkaline solution.

### REFERENCE

### Patent Document

[Patent Document 1]
Japanese Published Patent Application No 2003-258285

### SUMMARY OF THE INVENTIONS

In any case, the method in which the silicon substrate itself is etched to form the uneven structure on the surface of the silicon substrate is not favorable because the method has a problem in controllability of the uneven shape and affects the characteristics of the solar cell. In addition, since the alkaline solution and a large amount of water for cleaning are needed for etching of the silicon substrate and it is necessary to pay attention to the contamination of the silicon substrate, the method is also not favorable in terms of productivity.

Thus, an object of an embodiment of the present invention is to provide a photoelectric conversion device having a novel anti-reflection structure.

One feature of an embodiment of the present invention is to form an uneven structure on a surface of a semiconductor by growth of the same or a different kind of semiconductor instead of forming an anti-reflection structure by etching a surface of a semiconductor substrate or a semiconductor film.

For example, a semiconductor layer including a plurality of projections is provided on a light incident plane side of a photoelectric conversion device, thereby considerably reducing surface reflection. Such a structure can be formed by a vapor deposition method; therefore, the contamination of the semiconductor is not caused.

With the use of a vapor deposition method, a semiconductor layer including a plurality of whiskers can be grown, whereby the anti-reflection structure of the photoelectric conversion device can be formed.

An embodiment of the present invention is a photoelectric conversion device including a first conductive layer, a plurality of second conductive layers that is provided in contact with the first conductive layer, a first conductivity-type crystalline semiconductor region that is provided over the first conductive layer and the second conductive layer and has an uneven surface by including a plurality of whiskers which is formed using a crystalline semiconductor including an impurity element imparting the first conductivity, and a second-conductivity-type crystalline semiconductor region that covers the uneven surface of the first-conductivity-type crystalline semiconductor region having the uneven surface. The second conductivity type is opposite to the first conductivity type.

An embodiment of the present invention is a photoelectric conversion device including a first-conductivity-type crystalline semiconductor region and a second-conductivity-type crystalline semiconductor region that are stacked over an electrode. The electrode includes a first conductive layer and a plurality of second conductive layers. The first-conductivity-type crystalline semiconductor region includes a crystalline semiconductor region including an impurity element imparting the first conductivity, and a plurality of whiskers that is provided over the crystalline semiconductor region and includes a crystalline semiconductor including an impurity element imparting the first conductivity type. That is, since the first-conductivity-type crystalline semiconductor region includes the plurality of whiskers, a surface of the second-conductivity-type crystalline semiconductor region is uneven. In addition, an interface between the first-conductivity-type crystalline semiconductor region and the second-conductivity-type crystalline semiconductor region is uneven.

Note that a crystalline semiconductor region may be provided between the first-conductivity-type crystalline semiconductor region and the second-conductivity-type crystalline semiconductor region, and an interface between the first-conductivity-type crystalline semiconductor region and the crystalline semiconductor region may be uneven.

In the above photoelectric conversion device, the first-conductivity-type crystalline semiconductor region is one of an n-type semiconductor region and a p-type semiconductor region, and the second-conductivity-type crystalline semiconductor region is the other of the n-type semiconductor region and the p-type semiconductor region.

An embodiment of the present invention is a photoelectric conversion device including, in addition to the above structure, a third-conductivity-type semiconductor region, an intrinsic semiconductor region, and a fourth-conductivity-type semiconductor region that are stacked over the second-conductivity-type crystalline semiconductor region. Accordingly, a surface of the fourth-conductivity-type semiconductor region is uneven.

Note that in the above photoelectric conversion device, each of the first-conductivity-type crystalline semiconductor region and the third-conductivity-type semiconductor region is one of an n-type semiconductor region and a p-type semiconductor region, and each of the second-conductivity-type crystalline semiconductor region and the fourth-conductivity-type semiconductor region is the other of the n-type semiconductor region and the p-type semiconductor region.

Directions of axes of the plurality of whiskers which is provided over the first-conductivity-type crystalline semiconductor region may be the normal direction of the first conductive layer. Alternatively, the directions of axes of the plurality of whiskers which is provided over the first-conductivity-type crystalline semiconductor region may be varied.

The electrode includes a first conductive layer and a plurality of second conductive layers. The second conductive layer can be formed using a metal element which forms silicide by reacting with silicon. Alternatively, the second conductive layer can be formed with a layered structure of a layer which is formed using a material having high conductivity such as a metal element typified by platinum, aluminum, or copper, and a layer which is formed using a metal element forming silicide by reacting with silicon.

The electrode may include a mixed layer covering the plurality of second conductive layers. The mixed layer may include silicon and a metal element which forms the second conductive layer. In the case where the second conductive layer is formed using a metal element which forms silicide by reacting with silicon, the mixed layer may be formed of silicide.

In the photoelectric conversion device, the first-conductivity-type crystalline semiconductor region includes a plurality of whiskers, thereby reducing light reflectance at the surface. In addition, since the photoelectric conversion layer absorbs light incident on the photoelectric conversion layer owing to a light-trapping effect, characteristics of the photoelectric conversion device can be improved.

An embodiment of the present invention is a method for manufacturing a photoelectric conversion device, including the steps of: forming a second conductive layer over a first conductive layer; over the first conductive layer and the second conductive layer, forming a first-conductivity-type crystalline semiconductor region that includes a crystalline semiconductor region and a plurality of whiskers including a crystalline semiconductor by a low pressure CVD method using a deposition gas containing silicon and a gas imparting the first conductivity type as source gases; and forming a second-conductivity-type crystalline semiconductor region over the first-conductivity-type crystalline semiconductor region by a low pressure CVD method using a deposition gas containing silicon and a gas imparting the second conductivity type as source gases.

An embodiment of the present invention is a method for manufacturing a photoelectric conversion device, comprising the steps of: forming a second conductive layer over a first conductive layer; over the first conductive layer and the second conductive layer, forming a first-conductivity-type crystalline semiconductor region that includes a crystalline semiconductor region and a plurality of whiskers including a crystalline semiconductor by a low pressure CVD method using a deposition gas containing silicon and a gas imparting the first conductivity type as source gases; and forming a second-conductivity-type crystalline semiconductor region over the first-conductivity-type crystalline semiconductor region by a low pressure CVD method using a deposition gas containing silicon and a gas imparting the second conductivity type as source gases.

Note that the low pressure CVD method is performed at a temperature of higher than 550° C. In addition, silicon hydride, silicon fluoride, or silicon chloride may be used for the deposition gas containing silicon. In addition, the gas imparting the first conductivity type is one of diborane and phosphine, and the gas imparting the second conductivity type is the other of the diborane and the phosphine.

By a low pressure CVD method, the first-conductivity-type crystalline semiconductor region which includes the plurality of whiskers can be formed over the second conductive layer which is formed using a metal element forming silicide by reacting with silicon.

Note that in this specification, an “intrinsic semiconductor” refers to not only a so-called intrinsic semiconductor in which the Fermi level lies in the middle of the band gap, but a semiconductor in which the concentration of an impurity imparting p-type or n-type conductivity is 1×10²⁰ cm⁻³ or lower and photoconductivity is 100 times or more as high as the dark conductivity. This intrinsic semiconductor may include an impurity element belonging to Group 13 or Group 15 of the periodic table. Accordingly, if the problems can be solved and the same effect can be used, even the semiconductor having n-type or p-type conductivity can be used instead of the intrinsic semiconductor. Such a substantially intrinsic semiconductor is included in an intrinsic semiconductor in this specification.

According to an embodiment of the present invention, the surface of the second-conductivity-type crystalline semiconductor region is uneven, whereby the characteristics of the photoelectric conversion device can be improved.

### BRIEF DESCRIPTION OF THE DRAWINGS

In the accompanying drawings:

FIG. 1 is a top view illustrating a photoelectric conversion device;

FIG. 2 is a cross-sectional view illustrating a photoelectric conversion device;

FIG. 3 is a cross-sectional view illustrating a photoelectric conversion device;

FIG. 4 is a cross-sectional view illustrating a photoelectric conversion device;

FIGS. 5A to 5C are cross-sectional views illustrating a method for manufacturing a photoelectric conversion device;

FIGS. 6A and 6B are cross-sectional views illustrating a method for manufacturing a photoelectric conversion device;

FIG. 7 is a cross-sectional view illustrating a photoelectric conversion device;

FIG. 8 is a cross-sectional view illustrating a photoelectric conversion device; and

FIG. 9 is a cross-sectional view illustrating a photoelectric conversion device.

### DETAILED DESCRIPTION OF THE INVENTION

Hereinafter, embodiments of the present invention will be described with reference to the drawings. Note that the invention is not limited to the following description, and it will be easily understood by those skilled in the art that various changes and modifications can be made without departing from the spirit and scope of the invention. Thus, the present invention should not be interpreted as being limited to the following description of the embodiments. In description with reference to the drawings, in some cases, the same reference numerals are used in common for the same portions in different drawings. Further, in some cases, the same hatching patterns are applied to similar parts, and the similar parts are not necessarily designated by reference numerals.

Note that in each drawing described in this specification, the size, the layer thickness, or the region of each component is exaggerated for clarity in some cases. Therefore, embodiments of the present invention are not limited to such scales.

Note that terms such as “first”, “second”, and “third” in this specification are used in order to avoid confusion among components, and the terms do not limit the components numerically. Therefore, for example, the term “first” can be replaced with the term “second”, “third”, or the like as appropriate.

### Embodiment 1

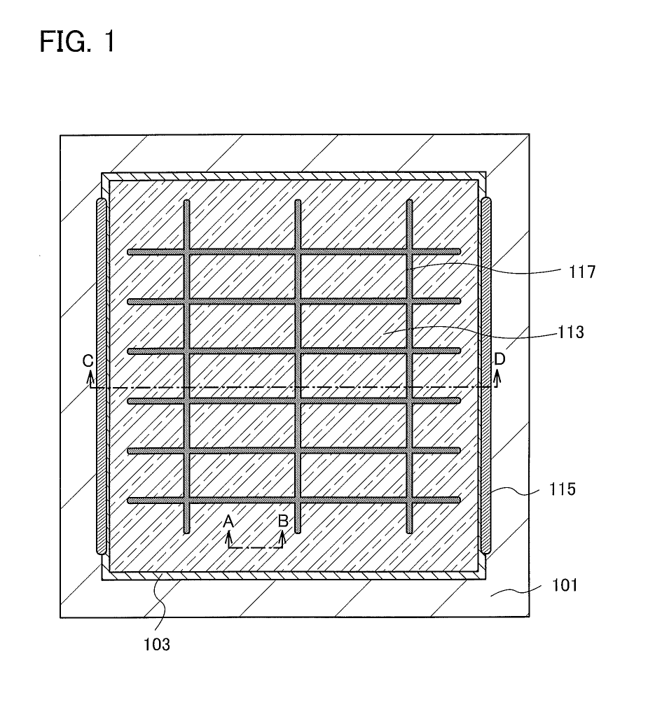

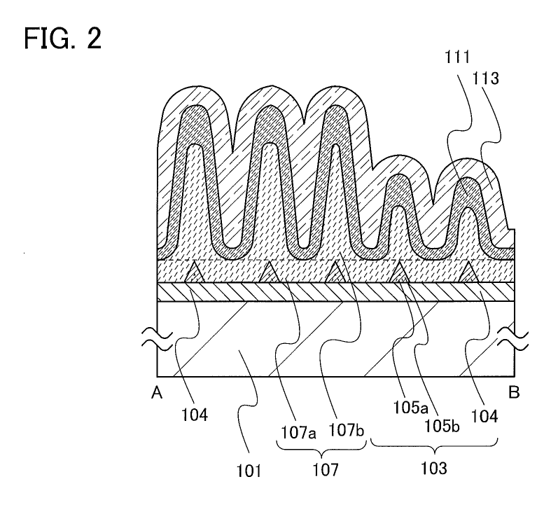

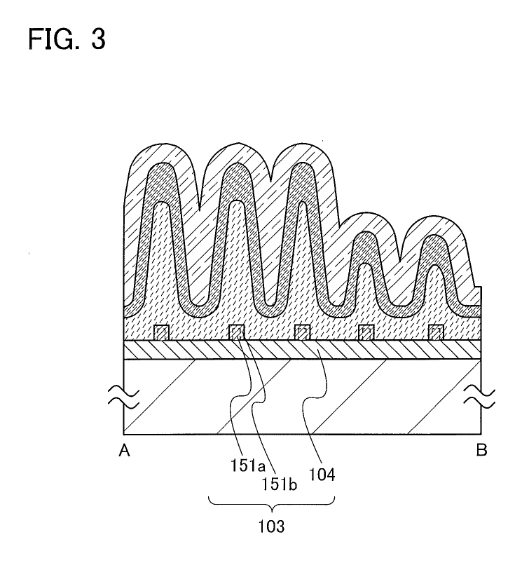

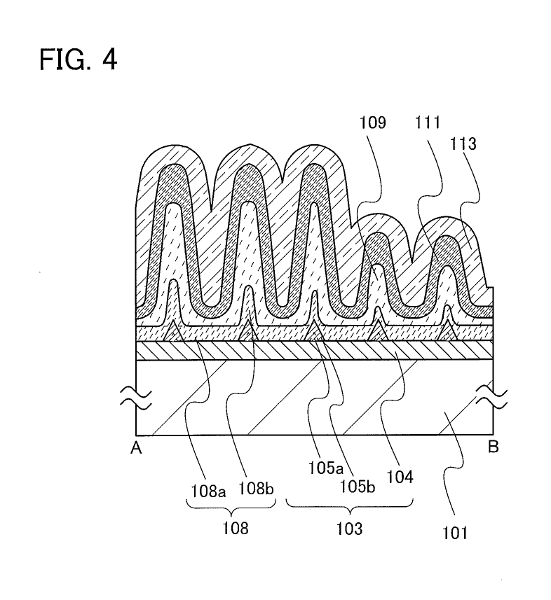

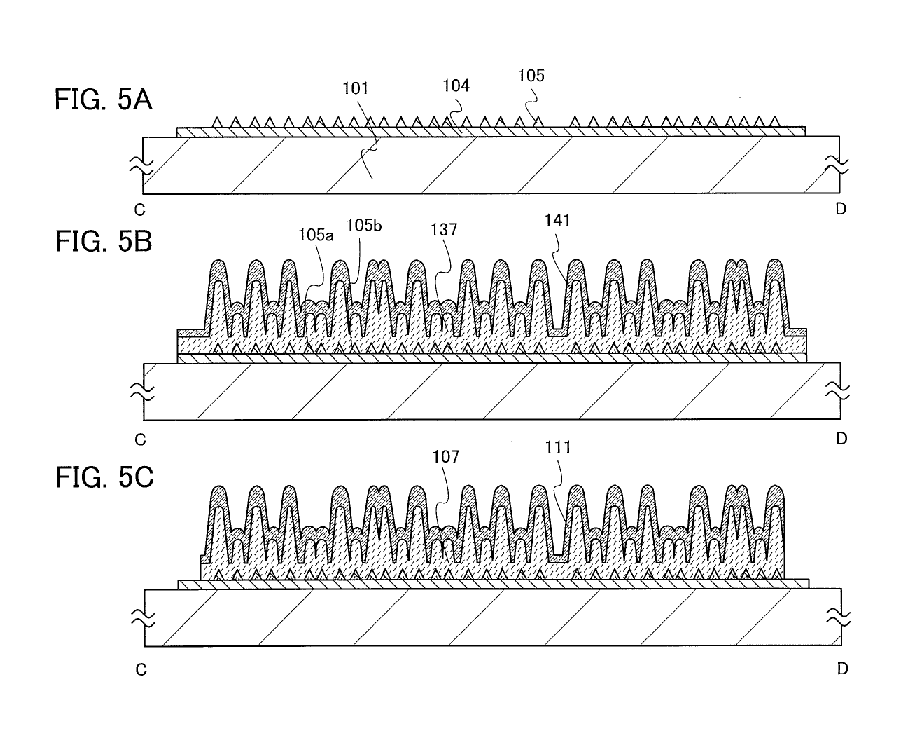

In this embodiment, a structure of a photoelectric conversion device which is one embodiment of the present invention is described with reference to FIG. 1, FIG. 2, FIG. 3, FIG. 4, and FIGS. 5A to 5C.

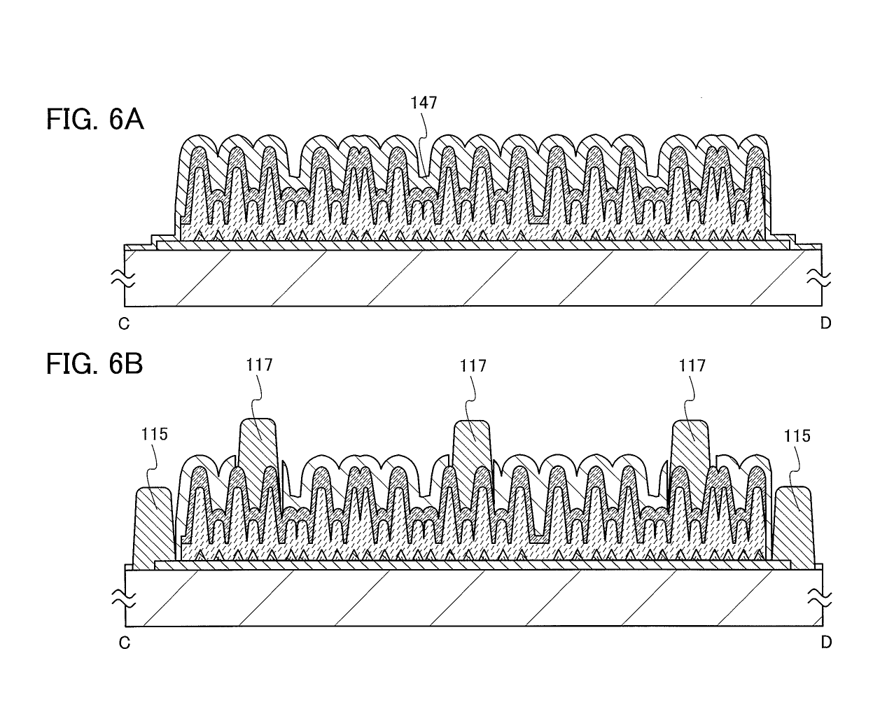

FIG. 1 is a schematic view of a top surface of a photoelectric conversion device. Although not illustrated, a photoelectric conversion layer is formed over an electrode 103 which is formed over a substrate 101. Further, an auxiliary electrode 115 is formed over the electrode 103 and a grid electrode 117 is formed over a second-conductivity-type crystalline semiconductor region. The auxiliary electrode 115 functions as a terminal for extracting electric energy to the outside. The grid electrode 117 is formed over the second-conductivity-type crystalline semiconductor region to reduce resistance of the second-conductivity-type crystalline semiconductor region. Here, a cross section of a dashed-and-dotted line A-B in FIG. 1 is described with reference to FIG. 2, FIG. 3, FIG. 4, FIGS. 5A to 5C, and FIGS. 6A and 6B.

FIG. 2 is a schematic view of a photoelectric conversion device including a substrate 101, an electrode 103, a first-conductivity-type crystalline semiconductor region 107, and a second-conductivity-type crystalline semiconductor region 111. The second conductivity type is opposite to the first conductivity type. The first-conductivity-type crystalline semiconductor region 107 and the second-conductivity-type crystalline semiconductor region 111 function as a photoelectric conversion layer. The first-conductivity-type crystalline semiconductor region 107 has an uneven surface by including a plurality of whiskers which are formed using a crystalline semiconductor including an impurity element imparting first conductivity type. In addition, an insulating layer 113 is formed over the second-conductivity-type crystalline semiconductor region 111.

In this embodiment, the first-conductivity-type crystalline semiconductor region 107 includes a crystalline semiconductor region 107a including an impurity element imparting the first conductivity type and a group of whiskers including a plurality of whiskers 107b which are formed using a crystalline semiconductor including an impurity element imparting the first conductivity type. Further, an interface between the first-conductivity-type crystalline semiconductor region 107 and the second-conductivity-type crystalline semiconductor region 111 is uneven. That is, a surface of the second-conductivity-type crystalline semiconductor region 111 is uneven.

The position and density of the whiskers 107b of the first-conductivity-type crystalline semiconductor region 107 can be controlled by changing the shape and size of a plurality of second conductive layers 105a formed over the first conductive layer 104 and the shape and size of a plurality of mixed layers 105b. That is, by the plurality of second conductive layers 105a and the plurality of mixed layers 105b which are formed over the first conductive layer 104, the crystalline semiconductor region 107a and the whiskers 107b can be formed. Thus, the second conductive layers 105a and the mixed layers 105b are overlapped with the whiskers 107b. In this embodiment, one whisker 107b overlaps with one mixed layer 105b.

In this embodiment, a p-type crystalline semiconductor layer and an n-type crystalline semiconductor layer are used as the first-conductivity-type crystalline semiconductor region 107 and the second-conductivity-type crystalline semiconductor region 111, respectively; however, the p-type conductivity and the n-type conductivity may be interchanged with each other.

As the substrate 101, a glass substrate typified by an aluminosilicate glass substrate, a barium borosilicate glass substrate, an aluminoborosilicate glass substrate, a sapphire glass substrate, and a quartz glass substrate can be used. Alternatively, a substrate in which an insulating film is formed over a metal substrate such as a stainless steel substrate or the like may be used. In this embodiment, a glass substrate is used as the substrate 101.

Note that in the electrode 103, a plurality of second conductive layers 105a is formed over the first conductive layer 104 in some cases. Alternatively, the electrode 103 includes, over the first conductive layer 104, the plurality of second conductive layers 105a and the plurality of mixed layers 105b formed on surfaces of the second conductive layers 105a in some cases. Further alternatively, in the electrode 103, a plurality of mixed layers 105b is formed over the first conductive layer 104 in some cases.

The first conductive layer 104 functions as an electrode of the photoelectric conversion layer. Thus, it is preferable that the first conductive layer 104 have the size which is adjusted to the size of the cell of the photoelectric conversion device. The first conductive layer 104 is formed using a conductive layer having a reflecting property or a light-transmitting property.

In the case where external light is incident on the photoelectric conversion device from the insulating layer 113 side, a reflective conductive layer is formed as the first conductive layer 104, whereby a light-trapping effect in the photoelectric conversion layer can be increased. The reflective conductive layer is preferably formed using a metal element having high conductivity and a reflecting property typified by aluminum, copper, tungsten, an aluminum alloy to which an element which improves heat resistance, such as silicon, titanium, neodymium, scandium, or molybdenum, is added, or the like.

In the case where external light is incident on the photoelectric conversion device from the electrode 103 side, a light-transmitting conductive layer is formed as the first conductive layer 104, whereby loss of the amount of light incident on the photoelectric conversion layer can be reduced. As the light-transmitting conductive layer, a conductive layer formed using an indium oxide-tin oxide alloy (ITO), zinc oxide (ZnO), tin oxide (SnO₂), zinc oxide containing aluminum, or the like is preferably used.

Note that the first conductive layer 104 may have a foil shape, a plate shape, or a net shape. With such a shape, the first conductive layer 104 can hold its shape by itself, and the substrate 101 is therefore not essential. For this reason, cost can be reduced. In addition, the first conductive layer 104 has a foil shape, whereby a flexible photoelectric conversion device can be manufactured.

The second conductive layer 105a is formed using a metal element which forms silicide by reacting with silicon. Alternatively, a stacked layer structure may be used, which includes a layer formed using a metal element having high conductivity typified by aluminum, copper, an aluminum alloy to which an element which improves heat resistance, such as silicon, titanium, neodymium, scandium, or molybdenum, is added, or the like on the substrate 101 side; and a layer formed using a metal element which forms silicide by reacting with silicon on the first-conductivity-type crystalline semiconductor region 107 side. Examples of the metal element which forms silicide by reacting with silicon include zirconium, titanium, hafnium, vanadium, niobium, tantalum, chromium, molybdenum, cobalt, nickel, and the like.

The second conductive layer 105a is preferably formed to a thickness of greater than or equal to 100 nm and less than or equal to 1000 nm.

The mixed layer 105b may be formed using silicon and the metal element which forms the second conductive layer 105a. Note that in the case where the mixed layer 105b is formed using silicon and the metal element which forms the second conductive layer 105a, active species of the source gas are supplied to a deposition portion depending on heating conditions in forming the first-conductivity-type crystalline semiconductor region by an LPCVD method; therefore, silicon is diffused into the second conductive layer 105a and thus the mixed layer 105b is formed.

In the case where the second conductive layer 105a is formed using a metal element which forms silicide by reacting with silicon, silicide including the metal element is formed in the mixed layer 105b; typically, one or more of zirconium silicide, titanium silicide, hafnium silicide, vanadium silicide, niobium silicide, tantalum silicide, chromium silicide, molybdenum silicide, cobalt silicide, and nickel silicide is/are formed. Alternatively, an alloy layer of silicon and a metal element which forms silicide is formed.

As illustrated in FIG. 2, the second conductive layer 105a and the mixed layer 105b can have a conical shape such as a circular cone or a pyramid or a polyhedral shape whose top surface has a vertex. Alternatively, as illustrated in FIG. 3, a second conductive layer 151a and a mixed layer 151b can have a columnar-like shape such as a cylinder or a prism, a polyhedral shape whose top surface is flat, or a truncated conical shape such as a circular truncated cone or a truncated pyramid. Note that the second conductive layers 105a and 151a and the mixed layers 105b and 151b may have rounded corners in which crests and vertexes are rounded in any of the above shapes. In the case where the mixed layer 105b is formed over the second conductive layer 105a, a stacked-layer structure thereof corresponds to the above structure.

In this embodiment, a whisker grows based on the second conductive layer 105a, or the mixed layers 105b and 151b. Therefore, when the width of the cross-sectional shapes of the second conductive layer 105a and/or the mixed layer 105b and the width of the cross-sectional shapes of the second conductive layer 151a and/or the mixed layer 151b are narrower than the width of the whisker 107b, the second conductive layer 105a and/or the mixed layer 105b and the second conductive layer 151a and/or the mixed layer 151b are overlapped with one whisker. Note that in the case where the second conductive layer 151a and/or the mixed layer 105b have/has a conical shape or a polyhedral shape, a whisker grows more easily based on a vertex.

In the case where the mixed layer 105b is provided between the second conductive layer 105a and the first-conductivity-type crystalline semiconductor region 107, resistance at an interface between the second conductive layer 105a and the first-conductivity-type crystalline semiconductor region 107 can be reduced; therefore series resistance can be further reduced as compared to the case where the first-conductivity-type crystalline semiconductor region 107 is directly stacked over the second conductive layer 105a. In addition, the adhesiveness between the second conductive layer 105a and the first-conductivity-type crystalline semiconductor region 107 can be increased. As a result, yield of the photoelectric conversion device can be improved.

The first-conductivity-type crystalline semiconductor region 107 is typically formed using a semiconductor to which an impurity element imparting the first conductivity type is added. Silicon is suitable for the semiconductor material, considering productivity, a price, or the like. When silicon is used as the semiconductor material, phosphorus or arsenic, which imparts n-type conductivity, or boron, which imparts p-type conductivity, is used as the impurity element imparting the first conductivity type. Here, the first-conductivity-type crystalline semiconductor region 107 is formed using a p-type crystalline semiconductor.

The first-conductivity-type crystalline semiconductor region 107 includes a crystalline semiconductor region 107a which includes an impurity element imparting the first conductivity type (hereinafter referred to as the crystalline semiconductor region 107a) and a group of whiskers including a plurality of whiskers 107b which is provided over the crystalline semiconductor region 107a and which is formed using a crystalline semiconductor including an impurity element imparting the first conductivity type (hereinafter referred to as the whiskers 107b). Note that the interface between the crystalline semiconductor region 107a and the whisker 107b is unclear. Therefore, a plane that is in the same level as the bottom of the deepest valley of valleys formed among whiskers 107b and is parallel to a surface of the electrode 103 is regarded as the interface between the crystalline semiconductor region 107a and the whisker 107b.

The crystalline semiconductor region 107a covers the second conductive layer 105a or the mixed layer 105b. In addition, the whisker 107b is a whisker-like protrusion, and a plurality of protrusions is dispersed. Note that the whisker 107b may have a columnar-like shape such as a cylinder or a prism, or a needle-like shape such as a cone or a pyramid. The top of the whisker 107b may be rounded. The width of the whisker 107b is greater than or equal to 100 nm and less than or equal to 10 μm, preferably greater than or equal to 500 nm and less than or equal to 3 μm. Further, the length in the axis of the whisker 107b is greater than or equal to 300 nm and less than or equal to 20 μm, preferably greater than or equal to 500 nm and less than or equal to 15 μm. The photoelectric conversion device in this embodiment includes one or more of the above-described whiskers.

Note that the length in the axis of the whisker 107b is the distance between the top of the whisker 107b and the crystalline semiconductor region 107a in the axis running through the top of the whisker 107b or the center of the top surface of the whisker 107b. The thickness of the first-conductivity-type crystalline semiconductor region 107 is the sum of the thickness of the crystalline semiconductor region 107a and the length of a normal from the top of the whisker 107b to the crystalline semiconductor region 107a (i.e., the height of the whisker). The width of the whisker 107b refers to a length of a longer axis of a transverse cross-sectional shape at the interface between the crystalline semiconductor region 107a and the whisker 107b.

Note that the direction in which the whisker 107b extends from the crystalline semiconductor region 107a is referred to as a longitudinal direction. A cross-sectional shape along the longitudinal direction is referred to as a longitudinal cross-sectional shape. In addition, the shape of a plane in which the longitudinal direction is a normal direction is referred to as a transverse cross-sectional shape.

In FIG. 2, the longitudinal directions of the whiskers 107b included in the first-conductivity-type crystalline semiconductor region 107 are one direction, e.g., the direction normal to the surface of the electrode 103. Note that the longitudinal direction of the whisker 107b may be substantially the same as the direction normal to the surface of the electrode 103. In that case, it is preferable that the difference between the angles of the directions be typically within 5°.

Note that the longitudinal directions of the whiskers 107b included in the first-conductivity-type crystalline semiconductor region 107 are one direction, e.g., the direction normal to the surface of the electrode 103 in FIG. 2; however, the longitudinal directions of the whiskers 107b may be varied. Typically, the first-conductivity-type crystalline semiconductor region 107 may include a whisker whose longitudinal direction is substantially the same as the normal direction and a whisker whose longitudinal direction is different from the normal direction.

The second-conductivity-type crystalline semiconductor region 111 is formed using an n-type crystalline semiconductor. Note that semiconductor materials which can be used for the second-conductivity-type crystalline semiconductor region 111 are the same as those for the first-conductivity-type crystalline semiconductor region 107.

In this embodiment, in the photoelectric conversion layer, an interface between the first-conductivity-type crystalline semiconductor region 107 and the second-conductivity-type crystalline semiconductor region 111 and the surface of the second-conductivity-type crystalline semiconductor region 111 are uneven. Therefore, reflectance of light incident on the insulating layer 113 can be reduced. Further, the light incident on the photoelectric conversion layer is efficiently absorbed by the photoelectric conversion layer due to a light-trapping effect; thus, the characteristics of the photoelectric conversion device can be improved. In the case where light is incident on the photoelectric conversion layer from the substrate 101 side, the first conductive layer 104 which is part of the electrode 103 may be formed using a light-transmitting conductive layer and a reflective conductive layer may be formed between the second-conductivity-type crystalline semiconductor region 111 and the insulating layer 113. Since the second-conductivity-type crystalline semiconductor region 111 is uneven, the light-trapping effect of the photoelectric conversion layer is increased and more light is absorbed by the photoelectric conversion layer, whereby the characteristics of the photoelectric conversion device can be improved.

Note that in FIG. 2 and FIG. 3, a PN junction semiconductor layer in which the first-conductivity-type crystalline semiconductor region 107 and the second-conductivity-type crystalline semiconductor region 111 are in contact with each other is used as the photoelectric conversion layer; however, as illustrated in FIG. 4, a PIN junction semiconductor layer which includes a crystalline semiconductor region 109 between a first-conductivity-type crystalline semiconductor region 108 and the second-conductivity-type crystalline semiconductor region 111 may be used as the photoelectric conversion layer. Here, as the crystalline semiconductor region 109, an intrinsic crystalline semiconductor region is used.

Note that in this specification, an “intrinsic semiconductor” refers to not only a so-called intrinsic semiconductor in which the Fermi level lies in the middle of the band gap, but a semiconductor in which the concentration of an impurity imparting p-type or n-type conductivity is 1×10²⁰ cm⁻³ or lower and the photoconductivity is 100 times or more as high as the dark conductivity. This intrinsic semiconductor includes an impurity element belonging to Group 13 or Group 15 of the periodic table. Such a substantially intrinsic semiconductor is included in the intrinsic semiconductor here.

Note that the first-conductivity-type crystalline semiconductor region 108 includes a crystalline semiconductor region 108a including an impurity element imparting the first conductivity type and a group of whiskers including a plurality of whiskers 108b which is provided over the crystalline semiconductor region 108a and which is formed using a crystalline semiconductor including an impurity element imparting the first conductivity type, like the first-conductivity-type crystalline semiconductor region 107 illustrated in FIG. 2.

Note that the insulating layer 113 which has an anti-reflection function and a protection function is preferably formed over exposed surfaces of the electrode 103 and the second-conductivity-type crystalline semiconductor region 111.

For the insulating layer 113, a material whose refractive index is between the refractive indices of the second-conductivity-type crystalline semiconductor region 111 and air is used. In addition, a material which transmits light with a predetermined wavelength is used so that incidence of light on the second-conductivity-type crystalline semiconductor region 111 is not interrupted. The use of such a material can prevent reflection at the light incident plane of the second-conductivity-type crystalline semiconductor region. Note that as such a material, silicon nitride, silicon nitride oxide, or magnesium fluoride can be given, for example.

Although not illustrated, an electrode may be provided over the second-conductivity-type crystalline semiconductor region 111. The electrode is formed using a light-transmitting conductive layer of an alloy of indium oxide and tin oxide (ITO), zinc oxide (ZnO), tin oxide (SnO₂), zinc oxide containing aluminum, or the like. In this embodiment, the light is incident on the second-conductivity-type crystalline semiconductor region 111 side; therefore, the second-conductivity-type crystalline semiconductor region 111 is formed using a light-transmitting conductive layer.

The auxiliary electrode 115 and the grid electrode 117 illustrated in FIG. 1 are formed of a layer formed using a metal element such as silver, copper, aluminum, palladium, lead, or tin. The grid electrode 117 is formed to be in contact with the second-conductivity-type crystalline semiconductor region 111, whereby the resistance loss of the second-conductivity-type crystalline semiconductor region 111 can be reduced, and especially, the electrical characteristics under high illuminance can be enhanced. The grid electrode has a grid pattern (or a comb-like pattern, a comb-like shape, or a comb-tooth-like pattern) in order to increase a light-receiving area of the photoelectric conversion layer.

Next, a method for manufacturing the photoelectric conversion device illustrated in FIG. 1 and FIG. 2 will be described with reference to FIGS. 5A to 5C and FIGS. 6A and 6B. Here, a cross section taken along a dashed-and-dotted line C-D in FIG. 1 will be described with reference to FIGS. 5A to 5C and FIGS. 6A and 6B.

As illustrated in FIG. 5A, the first conductive layer 104 is formed over the substrate 101. The first conductive layer 104 can be formed by a printing method, a sol-gel method, a coating method, an ink-jet method, a CVD method, a sputtering method, an evaporation method, or the like, as appropriate. Note that, in the case where the first conductive layer 104 has a foil shape, it is not necessary to provide the substrate 101. Further, roll-to-roll processing can be employed.

Next, a plurality of second conductive layers 105 is formed over the first conductive layer 104. The second conductive layer 105 is preferably formed assuming the position of the whisker included in the first-conductivity-type crystalline semiconductor region formed later.

The second conductive layer 105 is formed over the first conductive layer 104 by an ink-jet method, a nano-imprinting method, or the like. Alternatively, the second conductive layer 105 can be formed in the following manner that a conductive layer is formed over the first conductive layer 104 using a CVD method, a sputtering method, an evaporation method, a sol-gel method, or the like and then, a surface of the conductive layer is exposed to plasma until part of the first conductive layer 104 is exposed. Further alternatively, the second conductive layer 105 can be formed in the following manner that a conductive layer is formed over the first conductive layer 104, and then, the conductive layer is etched by using a resist mask formed by a photolithography process. Note that in this step, the above conductive layer needs to be formed using a layer formed using a metal element which having an etching selectivity with respect to the first conductive layer 104.

Next, as illustrated in FIG. 5B, a first-conductivity-type crystalline semiconductor region 137 and a second-conductivity-type crystalline semiconductor region 141 are formed by an LPCVD method. Then, a second electrode may be formed.

The LPCVD method is performed as follows: heating is performed at a temperature of higher than 550° C. and in the range of temperature at which an LPCVD apparatus and the conductive layer 104 can withstand, preferably higher than or equal to 580° C. and lower than 650° C.; at least a deposition gas containing silicon is used as a source gas; and the pressure in a reaction chamber of the LPCVD apparatus is set to higher than or equal to a lower limit at which the pressure can be maintained while the source gas flows and lower than or equal to 200 Pa. Examples of the deposition gas containing silicon include silicon hydride, silicon fluoride, and silicon chloride; typically, SiH₄, Si₂H₆, SiF₄, SiCl₄, Si₂Cl₆, and the like are given. Note that hydrogen may be introduced into the source gas.

When the first-conductivity-type crystalline semiconductor region 137 is formed by the LPCVD method, a mixed layer 105b is formed between the second conductive layer 105 and the first-conductivity-type crystalline semiconductor region 137 depending on heating conditions. In a step of forming the first-conductivity-type crystalline semiconductor region 137, active species of the source gas are constantly supplied to a deposition portion, and silicon is diffused from the first-conductivity-type crystalline semiconductor region 137 to the second conductive layer 105, so that the mixed layer 105b is formed. On the other hand, a region into which silicon is not diffused in the second conductive layer 105 becomes the second conductive layer 105a. For this reason, a low-density region (a sparse region) is not easily formed at an interface between the second conductive layer 105a and the first-conductivity-type crystalline semiconductor region 137. In addition, a plurality of minute second conductive layers 105a and a plurality of mixed layers 105b are formed over the first conductive layer 104; thus, a low-density region (a sparse region) is not easily formed at an interface between the first conductive layer 104 and the first-conductivity-type crystalline semiconductor region 137. For this reason, the characteristics of the interface between the first conductive layer 104 and the first-conductivity-type crystalline semiconductor region 137 are improved, so that series resistance can be reduced.

The first-conductivity-type crystalline semiconductor region 137 is formed by an LPCVD method in which diborane and a deposition gas containing silicon are introduced into the reaction chamber of the LPCVD apparatus as a source gas. The thickness of the first-conductivity-type crystalline semiconductor region 137 is greater than or equal to 500 nm and less than or equal to 20 μm. Here, a crystalline silicon layer to which boron is added is formed for the first-conductivity-type crystalline semiconductor region 137.

Next, the introduction of diborane into the reaction chamber of the LPCVD apparatus is stopped. Then, the second-conductivity-type crystalline semiconductor region 141 is formed by an LPCVD method in which phosphine or arsine and a deposition gas containing silicon are introduced into the reaction chamber of the LPCVD apparatus as a source gas. The thickness of the second-conductivity-type crystalline semiconductor region 141 is greater than or equal to 5 nm and less than or equal to 500 nm. Here, a crystalline silicon layer to which phosphorus or arsenic is added is formed for the second-conductivity-type crystalline semiconductor region 141.

Through the above steps, the photoelectric conversion layer including the first-conductivity-type crystalline semiconductor region 137 and the second-conductivity-type crystalline semiconductor region 141 can be formed.

A surface of the conductive layer 104 may be cleaned with hydrofluoric acid before the formation of the first-conductivity-type crystalline semiconductor region 137. This step can enhance the adhesiveness between the electrode 103 and the first-conductivity-type crystalline semiconductor region 137.

Further, nitrogen or a rare gas such as helium, neon, argon, or xenon may be added to the source gas of the first-conductivity-type crystalline semiconductor region 137 and the source gas of the second-conductivity-type crystalline semiconductor region 141. In the case where a rare gas or nitrogen is added to the source gas of the first-conductivity-type crystalline semiconductor region 137 and the source gas of the second-conductivity-type crystalline semiconductor region 141, the density of whiskers can be increased.

After the formation of the first-conductivity-type crystalline semiconductor region 137 or the formation of the second-conductivity-type crystalline semiconductor region 141, in the case where introduction of the source gas into the reaction chamber of the LPCVD apparatus is stopped and the temperature is maintained in a vacuum state (i.e., vacuum heating), the density of whiskers included in the first-conductivity-type crystalline semiconductor region 137 can be increased.

Next, a mask is formed over the second-conductivity-type crystalline semiconductor region 141, and then the first-conductivity-type crystalline semiconductor region 137 and the second-conductivity-type crystalline semiconductor region 141 are etched with use of the mask. As a result, the first conductive layer 104 is partly exposed, and the first-conductivity-type crystalline semiconductor region 107 and the second-conductivity-type crystalline semiconductor region 111 can be formed as illustrated in FIG. 5C.

Then, as illustrated in FIG. 6A, an insulating layer 147 is formed over the substrate 101, the first conductive layer 104, the first-conductivity-type crystalline semiconductor region 107, and the second-conductivity-type crystalline semiconductor region 111. The insulating layer 147 can be formed by a CVD method, a sputtering method, an evaporation method, or the like.

After that, the insulating layer 147 is partly etched so that part of the first conductive layer 104 and part of the second-conductivity-type crystalline semiconductor region 111 are exposed. Next, as in illustrated FIG. 6B, the auxiliary electrode 115 connected to the first conductive layer 104 is formed in an exposed portion of the conductive layer 104, and the grid electrode 117 connected to the second-conductivity-type crystalline semiconductor region 111 is formed in an exposed portion of the second-conductivity-type crystalline semiconductor region 111. The auxiliary electrode 115 and the grid electrode 117 can be formed by a printing method, a coating method, an ink-jet method, or the like.

Through the above steps, a photoelectric conversion device with high conversion efficiency can be manufactured.

### Embodiment 2

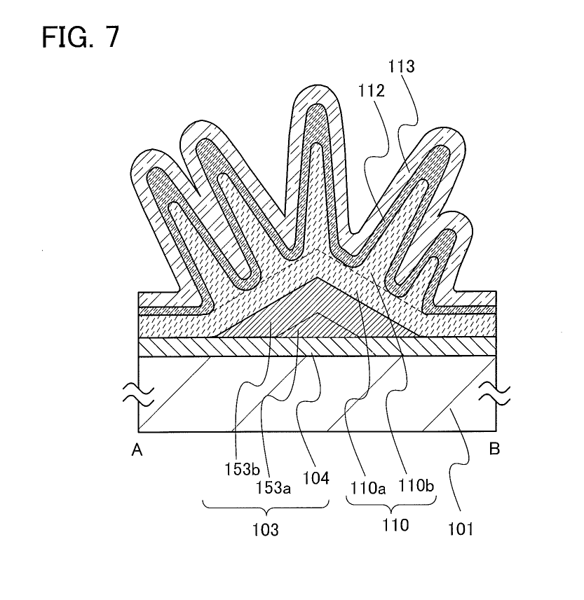

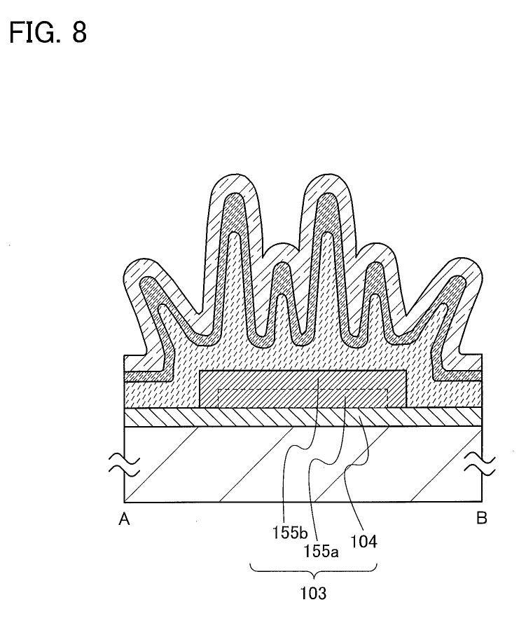

In this embodiment, a photoelectric conversion device in which the size of a second conductive layer and the size of a mixed layer are different as compared to those in Embodiment 1 is described with reference to FIG. 7 and FIG. 8.

The cross section of the dashed-and-dotted line A-B in FIG. 1 is described with reference to FIG. 7 and FIG. 8.

FIG. 7 is a schematic view of a photoelectric conversion device including the substrate 101, the electrode 103, a first-conductivity-type crystalline semiconductor region 110, and a second-conductivity-type crystalline semiconductor region 112. The second conductivity type is opposite to the first conductivity type. The first-conductivity-type crystalline semiconductor region 110 and the second-conductivity-type crystalline semiconductor region 112 function as a photoelectric conversion layer.

In this embodiment, the electrode 103 includes the first conductive layer 104, a plurality of second conductive layers 153a formed over the first conductive layer 104, and a plurality of mixed layers 153b covering surfaces of the second conductive layers 153a. Note that although only one pair of the second conductive layer 153a and the mixed layer 153b is illustrated in FIG. 7, plural pairs thereof are formed in the photoelectric conversion device.

In addition, the first-conductivity-type crystalline semiconductor region 110 includes a crystalline semiconductor region 110a which is formed using a crystalline semiconductor including an impurity element imparting the first conductivity type and a group of whiskers including a plurality of whiskers 110b which is formed over the crystalline semiconductor region 110a and which is formed using a crystalline semiconductor including an impurity element imparting the first conductivity type.

In this embodiment, a structure in which the plurality of whiskers 110b overlaps with one mixed layer 153b is described.

In this embodiment, when the width of the cross section of the second conductive layer 153a and the width of the cross section of the mixed layer 153b are 2 times or more, preferably 5 times or more as large as that of the whisker 110b, the plurality of whiskers 110b overlaps with the one mixed layer 153b.

Note that the plurality of second conductive layers 153a and the plurality of mixed layers 153b which are formed over the first conductive layer 104 control the position and density of the whiskers 110b of the first-conductivity-type crystalline semiconductor region 110. In other words, the crystalline semiconductor region 110a and the whiskers 110b can be formed based on the plurality of second conductive layers 153a and the plurality of mixed layers 153b which are formed over the first conductive layer 104. This is because the growth directions of the whiskers 110b are different due to a vertex or a plane of the mixed layer 153b. The directions of the axes of the whiskers 110b are varied.

The second conductive layer 153a and the mixed layer 153b can have the same cross-sectional shapes as those of the second conductive layer 105a and the mixed layer 105b in Embodiment 1. For example, in the case where the second conductive layer 153a and the mixed layer 153b are cones or polyhedrons as illustrated in FIG. 7, a vertex is formed in the normal direction of the substrate 101. Thus, a whisker extending in the normal direction based on the vertex is formed, and a whisker extending in a direction perpendicular to the face of the mixed layer 153b is also formed.

As illustrated in FIG. 8, when a second conductive layer 155a and a mixed layer 155b have a columnar-like shape, a polyhedral shape whose top surface is flat, or a truncated conical shape, a whisker extending in the normal direction based on the vertex is formed, and a whisker extending in a direction perpendicular to a plane of the mixed layer 155b is also formed.

Note that the second conductive layers 153a and 155a can be formed using the same material and with the same thickness as those of the second conductive layer 105a in Embodiment 1. In addition, the mixed layers 153b and 155b can be formed using the same material and with the same thickness as those of the mixed layer 105b in Embodiment 1.

An interface between the first conductive layer 104 and the first-conductivity-type crystalline semiconductor region 110 is flat. Further, the first-conductivity-type crystalline semiconductor region 110 includes the plurality of whiskers 110b. Thus, a surface of the first conductive layer 104 in contact with the first-conductivity-type crystalline semiconductor region 110 is flat, and a surface of the second-conductivity-type crystalline semiconductor region 112 is uneven. In addition, an interface between the first-conductivity-type crystalline semiconductor region 110 and the second-conductivity-type crystalline semiconductor region 112 is uneven.

Note that an interface between the crystalline semiconductor region 110a and the whisker 110b is unclear. Therefore, a plane that is in the same level as the bottom of the deepest valley of valleys formed among whiskers 110b and that is parallel to a surface of the first conductive layer 104 and to a surface of the second conductive layer 153a or a surface of the mixed layer 153b is regarded as the interface between the crystalline semiconductor region 110a and the whisker 110b.

The whisker 110b has a shape similar to that of the whisker 107b in Embodiment 1.

As described in this embodiment, when the width of the second conductive layer which functions as part of the electrode and that of the mixed layer are greater than that of the whisker, whiskers whose axes directions are varied are formed. Thus, the reflectance of light on the surface of the second-conductivity-type crystalline semiconductor region 112 can be reduced. Further, the light incident on the photoelectric conversion layer is absorbed by the photoelectric conversion layer due to a light-trapping effect; therefore, the characteristics of the photoelectric conversion device can be improved. In the case where light is incident on the photoelectric conversion layer from the substrate 101 side, the first conductive layer 104 which is part of the electrode 103 may be formed using a light-transmitting conductive layer and a reflective conductive layer may be formed between the second-conductivity-type crystalline semiconductor region 112 and the insulating layer 113. Since the second-conductivity-type crystalline semiconductor region 112 is uneven, the light-trapping effect of the photoelectric conversion layer is increased and more light is absorbed by the photoelectric conversion layer, so that the characteristics of the photoelectric conversion device can be improved.

### Embodiment 3

In this embodiment, a method for manufacturing a photoelectric conversion layer which has fewer defects than the photoelectric conversion layer in Embodiment 1 is described.

After one or more of the first-conductivity-type crystalline semiconductor region 107, the first-conductivity-type crystalline semiconductor region 108, the first-conductivity-type crystalline semiconductor region 110, the crystalline semiconductor region 109, the second-conductivity-type crystalline semiconductor region 111, and the second-conductivity-type crystalline semiconductor region 112, which are described in Embodiments 1 and 2, are formed, the temperature of a reaction chamber in an LPCVD apparatus is set at a temperature of higher than or equal to 400° C. and lower than or equal to 450° C., introduction of a source gas into the LPCVD apparatus is stopped, and hydrogen is introduced. Then, in a hydrogen atmosphere, heat treatment at a temperature of higher than or equal to 400° C. and lower than or equal to 450° C. is performed. In this manner, dangling bonds in one or more of the first-conductivity-type crystalline semiconductor region 107, the first-conductivity-type crystalline semiconductor region 108, the first-conductivity-type crystalline semiconductor region 110, the crystalline semiconductor region 109, the second-conductivity-type crystalline semiconductor region 111, and the second-conductivity-type crystalline semiconductor region 112 can be terminated with hydrogen. The heat treatment is also referred to as a hydrogenation treatment. As a result of the heat treatment, defects in one or more of the first-conductivity-type crystalline semiconductor region 107, the first-conductivity-type crystalline semiconductor region 108, the first-conductivity-type crystalline semiconductor region 110, the crystalline semiconductor region 109, the second-conductivity-type crystalline semiconductor region 111, and the second-conductivity-type crystalline semiconductor region 112 can be reduced, which leads to less recombination of photoexcited carriers in defects and also leads to an increase in conversion efficiency of the photoelectric conversion device.

Note that this embodiment can be applied to other embodiments.

### Embodiment 4

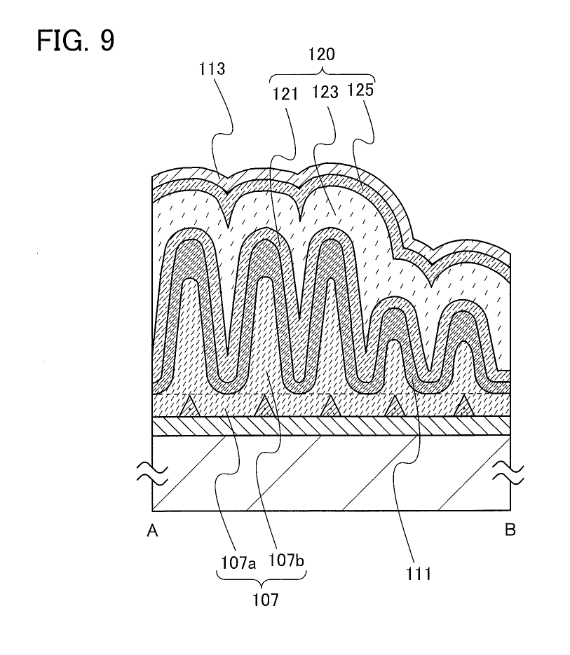

In this embodiment, the structure of a so-called tandem photoelectric conversion device in which a plurality of photoelectric conversion layers is stacked will be described with reference to FIG. 9. Although two photoelectric conversion layers are stacked in this embodiment, three or more photoelectric conversion layers may be stacked. In the following description, the photoelectric conversion layer which is closest to the light incident surface may be referred to as a top cell and the photoelectric conversion layer which is farthest from the light incident surface may be referred to as a bottom cell.

FIG. 9 illustrates a photoelectric conversion device in which the substrate 101, the electrode 103, the photoelectric conversion layer 106 which is the bottom cell, a photoelectric conversion layer 120 which is the top cell, and the insulating layer 113 are stacked. Here, the photoelectric conversion layer 106 includes the first-conductivity-type crystalline semiconductor region 107 and the second-conductivity-type crystalline semiconductor region 111 which are described in Embodiment 1. The photoelectric conversion layer 120 includes a third-conductivity-type semiconductor region 121, an intrinsic semiconductor region 123, and a fourth-conductivity-type semiconductor region 125. The band gap of the photoelectric conversion layer 106 is preferably different from that of the photoelectric conversion layer 120. Use of semiconductors having different band gaps makes it possible to absorb a wide wavelength range of light; thus, a photoelectric conversion efficiency can be improved.

For example, a semiconductor with a large band gap can be used for the top cell while a semiconductor with a small band gap can be used for the bottom cell, and needless to say, vice versa. Here, as an example, a structure where a crystalline semiconductor (typically, crystalline silicon) is used in the photoelectric conversion layer 106, which is the bottom cell, and an amorphous semiconductor (typically, amorphous silicon) is used in the photoelectric conversion layer 120, which is the top cell, is described.

Note that although a structure where light is incident on the fourth-conductivity-type semiconductor region 125 is described in this embodiment, one embodiment of the disclosed invention is not limited thereto. Light may be incident on the rear surface of the substrate 101 (the lower surface in the drawing). In this case, the substrate 101 and the first conductive layer 104 each have a light-transmitting property.

The structures of the substrate 101, the electrode 103, the photoelectric conversion layer 106, and the insulating layer 113 are similar to those in the above embodiments and description thereof is omitted here.

In the photoelectric conversion layer 120, which is the top cell, a semiconductor layer including a semiconductor material to which an impurity element imparting a conductivity type is added is typically used as the third-conductivity-type semiconductor region 121 and the fourth-conductivity-type semiconductor region 125. Details of the semiconductor material and the like are similar to those of the first-conductivity-type crystalline semiconductor region 107 in Embodiment 1. In this embodiment, the case where silicon is used as the semiconductor material, the third conductivity type is p-type, and the fourth conductivity type is n-type is described. In addition, the crystallinity of the semiconductor layer is amorphous. It is needless to say that the third conductivity type may be n-type, the fourth conductivity type may be p-type, and the semiconductor layer may be a crystalline semiconductor.

For the intrinsic semiconductor region 123, silicon, silicon carbide, germanium, gallium arsenide, indium phosphide, zinc selenide, gallium nitride, silicon germanium, or the like is used. Alternatively, a semiconductor material including an organic material, a metal oxide semiconductor material, or the like can be used.

In this embodiment, amorphous silicon is used for the intrinsic semiconductor region 123. The thickness of the intrinsic semiconductor region 123 is greater than or equal to 50 nm and less than or equal to 1000 nm, preferably greater than or equal to 100 nm and less than or equal to 450 nm. It is needless to say that the intrinsic semiconductor region 123 may be formed using a semiconductor material which is not silicon and has a band gap different from that of the crystalline semiconductor region 109 in the bottom cell. Here, the thickness of the intrinsic semiconductor region 123 is preferably smaller than that of the crystalline semiconductor region 109.

A plasma CVD method, an LPCVD method, or the like may be employed for forming the third-conductivity-type semiconductor region 121, the intrinsic semiconductor region 123, and the fourth-conductivity-type semiconductor region 125. In the case of a plasma CVD method, the intrinsic semiconductor region 123 can be formed in such a manner that the pressure in a reaction chamber of a plasma CVD apparatus is typically greater than or equal to 10 Pa and less than or equal to 1332 Pa, hydrogen and a deposition gas containing silicon are introduced as a source gas to the reaction chamber, and high-frequency electric power is supplied to an electrode to cause glow discharge. The third-conductivity-type semiconductor region 121 can be formed using the above source gas to which diborane is added. The third-conductivity-type semiconductor region 121 is formed with a thickness of greater than or equal to 1 nm and less than or equal to 100 nm, preferably greater than or equal to 5 nm and less than or equal to 50 nm. The fourth-conductivity-type semiconductor region 125 can be formed using the above source gas to which phosphine or arsine is added. The fourth-conductivity-type semiconductor region 125 is formed with a thickness of greater than or equal to 1 nm and less than or equal to 100 nm, preferably greater than or equal to 5 nm and less than or equal to 50 nm.

Alternatively, the third-conductivity-type semiconductor region 121 may be formed by forming an amorphous silicon layer by a plasma CVD method or an LPCVD method without adding an impurity element imparting a conductivity type and then adding boron by a method such as ion injection. The fourth-conductivity-type semiconductor region 125 may be formed by forming an amorphous silicon layer by a plasma CVD method or an LPCVD method without adding an impurity element imparting a conductivity type and then adding phosphorus or arsenic by a method such as ion injection.

As described above, by using amorphous silicon for the photoelectric conversion layer 120, light having a wavelength of less than 800 nm can be effectively absorbed and subjected to photoelectric conversion. Further, by using crystalline silicon for the photoelectric conversion layer 106, light having a longer wavelength (e.g., a wavelength up to approximately 1200 nm) can be absorbed and subjected to photoelectric conversion. Such a structure (a so-called tandem structure) in which photoelectric conversion layers having different band gaps are stacked can significantly increase a photoelectric conversion efficiency.

Note that although amorphous silicon having a large band gap is used in the top cell and crystalline silicon having a small band gap is used in the bottom cell in this embodiment, one embodiment of the disclosed invention is not limited thereto. The semiconductor materials having different band gaps can be used in appropriate combination to form the top cell and the bottom cell. The structure of the top cell and the structure of the bottom cell can be replaced with each other to form the photoelectric conversion device. Alternatively, a stacked structure in which three or more photoelectric conversion layers are stacked can be employed.

With the above structure, the conversion efficiency of a photoelectric conversion device can be increased.

Note that this embodiment can be applied to other embodiments.

This application is based on Japanese Patent Application serial no. 2010-139997 filed with Japan Patent Office on Jun. 18, 2010, the entire contents of which are hereby incorporated by reference.

What is claimed is:

1. A photoelectric conversion device comprising:
a first conductive layer;
a plurality of second conductive layers over the first conductive layer, the plurality of second conductive layers being in contact with the first conductive layer;
a first semiconductor region over the first conductive layer and the plurality of second conductive layers, the first semiconductor region comprising a plurality of whiskers; and
a second semiconductor region over the first semiconductor region, the second semiconductor region having an uneven surface,
wherein each of the first semiconductor region and the second semiconductor region is a crystalline semiconductor region, and
wherein the first semiconductor region and the second semiconductor region have different types of conductivity.

2. The photoelectric conversion device according to claim 1,
wherein the first semiconductor region is in contact with the second semiconductor region, and
wherein an interface between the first semiconductor region and the second semiconductor region is uneven.

3. The photoelectric conversion device according to claim 1, further comprising
a third semiconductor region between the first semiconductor region and the second semiconductor region,
wherein the third semiconductor region is a crystalline semiconductor region comprising an impurity element imparting conductivity,
wherein the first semiconductor region is in contact with the third semiconductor region, and
wherein an interface between the first semiconductor region and the third semiconductor region is uneven.

4. The photoelectric conversion device comprising according to claim 1, further comprising a third semiconductor region over the second semiconductor region, an intrinsic semiconductor region over the third semiconductor region, and a fourth semiconductor region over the intrinsic semiconductor region,
wherein each of the third semiconductor region and the fourth semiconductor region comprises an impurity element imparting conductivity.

5. The photoelectric conversion device according to claim 4, further comprising an intrinsic crystalline semiconductor region between the first semiconductor region and the second semiconductor region,
wherein the first semiconductor region is in contact with the intrinsic crystalline semiconductor region, and
wherein an interface between the first semiconductor region and the intrinsic crystalline semiconductor region is uneven.

6. The photoelectric conversion device according to claim 5, wherein a band gap of the intrinsic crystalline semiconductor region is different from a band gap of the intrinsic semiconductor region.

7. The photoelectric conversion device according to claim 4,
wherein each of the first semiconductor region and the third semiconductor region is one of an n-type semiconductor region and a p-type semiconductor region, and
wherein each of the second semiconductor region and the fourth semiconductor region is the other of the n-type semiconductor region and the p-type semiconductor region.

8. The photoelectric conversion device according to claim 1, wherein directions of axes of the plurality of whiskers are varied.

9. The photoelectric conversion device according to claim 1, wherein directions of axes of the plurality of whiskers are a normal direction of the first conductive layer.

10. The photoelectric conversion device according to claim 1, wherein each of the plurality of second conductive layers has a conical shape, a polyhedral shape, a columnar-like shape, or a truncated conical shape.

11. The photoelectric conversion device according to claim 1,
wherein a thickness of the first semiconductor region is greater than or equal to 5 nm and less than or equal to 500 nm.

12. A photoelectric conversion device comprising:
a first conductive layer;
a second conductive layer over the first conductive layer, the second conductive layer being in contact with the first conductive layer;
a third conductive layer over the first conductive layer, the third conductive layer being in contact with the first conductive layer;
a first semiconductor region over the first conductive layer, the second conductive layer and the third conductive layer, the first semiconductor region comprising a first whisker and a second whisker; and
a second semiconductor region over the first semiconductor region, the second semiconductor region having an uneven surface,
wherein each of the first semiconductor region and the second semiconductor region is a crystalline semiconductor region, and
wherein the first semiconductor region and the second semiconductor region have different types of conductivity.

13. The photoelectric conversion device according to claim 12,
wherein the first semiconductor region is in contact with the second semiconductor region, and
wherein an interface between the first semiconductor region and the second semiconductor region is uneven.

14. The photoelectric conversion device according to claim 12, further comprising a third semiconductor region between the first semiconductor region and the second semiconductor region,
wherein the third semiconductor region is a crystalline semiconductor region comprising an impurity element imparting conductivity,
wherein the first semiconductor region is in contact with the third semiconductor region, and
wherein an interface between the first semiconductor region and the third semiconductor region is uneven.

15. The photoelectric conversion device comprising according to claim 12, further comprising a third semiconductor region over the second semiconductor region, an intrinsic semiconductor region over the third semiconductor region, and a fourth semiconductor region over the intrinsic semiconductor region,
wherein each of the third semiconductor region and the fourth semiconductor region comprises an impurity element imparting conductivity.

16. The photoelectric conversion device according to claim 15, further comprising an intrinsic crystalline semiconductor region between the first semiconductor region and the second semiconductor region,
wherein the first semiconductor region is in contact with the intrinsic crystalline semiconductor region, and
wherein an interface between the first semiconductor region and the intrinsic crystalline semiconductor region is uneven.

17. The photoelectric conversion device according to claim 16, wherein a band gap of the intrinsic crystalline semiconductor region is different from a band gap of the intrinsic semiconductor region.

18. The photoelectric conversion device according to claim 15,
wherein each of the first semiconductor region and the third semiconductor region is one of an n-type semiconductor region and a p-type semiconductor region, and
wherein each of the second semiconductor region and the fourth semiconductor region is the other of the n-type semiconductor region and the p-type semiconductor region.

19. The photoelectric conversion device according to claim 12, wherein directions of axes of the first whisker and the second whisker are varied.

20. The photoelectric conversion device according to claim 12, wherein directions of axes of the first whisker and the second whisker are a normal direction of the first conductive layer.

21. The photoelectric conversion device according to claim 12, wherein the second conductive layer has a conical shape, a polyhedral shape, a columnar-like shape, or a truncated conical shape.

22. The photoelectric conversion device according to claim 12,
wherein the second conductive layer is overlapped with the first whisker, and
wherein the third conductive layer is overlapped with the second whisker.

23. The photoelectric conversion device according to claim 12, wherein the second conductive layer is overlapped with the first whisker and the second whisker.

24. The photoelectric conversion device according to claim 12,
wherein a width of the first whisker is greater than or equal to 100 nm and less than or equal to 10 μm, and
wherein a length of axis of the first whisker is greater than or equal to 300 nm and less than or equal to 20 μm.

25. The photoelectric conversion device according to claim 12,
wherein a thickness of the first semiconductor region is greater than or equal to 5 nm and less than or equal to 500 nm.

26. A method for manufacturing a photoelectric conversion device, comprising the steps of:
forming a plurality of second conductive layers over a first conductive layer;
forming a first semiconductor region over the first conductive layer and the plurality of second conductive layers by a low pressure CVD method using a deposition gas containing silicon and a gas imparting a first conductivity type as source gases,
wherein the first semiconductor region is a crystalline semiconductor region comprising an impurity element imparting conductivity, and
wherein the first semiconductor region comprises a plurality of whiskers.

27. A method for manufacturing a photoelectric conversion device according to claim 26, further comprising the step of:
forming a second semiconductor region over the first semiconductor region by a low pressure CVD method using a deposition gas containing silicon and a gas imparting a second conductivity type as source gases,
wherein the second semiconductor region is a crystalline semiconductor region comprising an impurity element imparting conductivity.

28. A method for manufacturing a photoelectric conversion device according to claim 26, further comprising the steps of:
forming an intrinsic crystalline semiconductor region over the first semiconductor region by a low pressure CVD method using a deposition gas containing silicon as a source gas; and
forming a second semiconductor region over the intrinsic crystalline semiconductor region by a low pressure CVD method using a deposition gas containing silicon and a gas imparting a second conductivity type as source gases,
wherein the second semiconductor region is a crystalline semiconductor region comprising an impurity element imparting conductivity.

29. The method for manufacturing a photoelectric conversion device, according to claim 26, wherein the low pressure CVD method is performed at a temperature of higher than 550° C.

30. The method for manufacturing a photoelectric conversion device, according to claim 26, wherein silicon hydride, silicon fluoride, or silicon chloride is used for the deposition gas containing silicon.

31. The method for manufacturing a photoelectric conversion device, according to claim 26,
wherein the gas imparting a first conductivity type is one of diborane and phosphine, and
wherein the gas imparting a second conductivity type is the other of the diborane and the phosphine.
